(19) United States
(12) Patent Application Publication
(10) Pub. No.: US 2025/0116058 A1
(43) Pub. Date: Apr. 10, 2025

(54) COMPLEX REDUCING THE CONDENSATION OF WATER, ARTICLE COMPRISING SUCH A COMPLEX, AND METHOD FOR PRODUCING SUCH A COMPLEX

(71) Applicant: DECATHLON, VILLENEUVE D’ASCQ (FR)

(72) Inventors: Liza GONCALVES, VILLENEUVE D’ASCQ (FR); Inès GOURLET, VILLENEUVE D’ASCQ (FR)

(21) Appl. No.: 18/730,016

(22) PCT Filed: Jan. 19, 2023
(86) PCT No.: PCT/EP2023/051166

§ 371 Date: Jul. 18, 2024

(30) Foreign Application Priority Data
Jan. 20, 2022 (FR) FR2200491

(51) Int. Cl. D06M 11/83; D06M 11/46; E04H 15/54

(52) U.S. Cl. CPC D06M 11/83; D06M 11/46; E04H 15/54; D06M 2200/12; D10B 2401/021

(57) ABSTRACT

The present invention relates to a complex (10) reducing the condensation of water, having an inner face (12) and an outer face (14), said outer face (14) being oriented directly facing the outside atmosphere, and said complex (10) comprises, from the inner face (12) towards the outer face (14): a substrate A that is impermeable to water and permeable to water vapour (20, 26), a textile substrate B (30); and at least one metal M1, optionally in the form of an alloy, deposited directly on the textile substrate B (30) and forming a metal layer C (40). The present invention also relates to an article comprising such a complex (10), a method for producing such a complex (10) and the use of said complex (10) for producing an article limiting the condensation of water on an interior wall.

### TECHNICAL FIELD

The present disclosure relates to the technical field of complexes reducing the condensation of water, in particular on their inner faces, as well as the methods for producing such complexes.

The present disclosure also relates to articles (for example a tent, awning, blind, sleeping bag over-bag, etc.) comprising a sheltered area, configured to receive at least one user, and further comprising said complex reducing the condensation of water in order to limit, optionally prevent, the runoff of dew water onto the users and/or the object sheltered by said articles.

### BACKGROUND

The textiles of articles intended to protect their users from the outside environment (sun, rain, wind, etc.), in particular in the field of camping for example tents, shelters, blinds, awnings, sunshades, etc.) and in general for the practice of sporting activities (garment for protection against bad weather such as a mountain jacket, sleeping bag over-bag, protection tarpaulin, sailing dungarees, etc.), are coated on one of their faces in order to ensure their impermeability to water. However, the applied coating greatly, or even totally, reduces the permeability of the textile to air and water vapour.

While sleeping and, in general, sheltering using said article, a person produces water vapour continuously. This quantity of water vapour adds to the natural humidity present in the sheltered area of said article, for example in the tent. At night, the outside temperature drops more quickly than that inside the sheltered area of said article, for example inside the tent. On contact with the inner face of the cold wall separating the inside of the sheltered area from the outside of the sheltered area, water vapour contained in the sheltered area condenses on the inner face then runs off or falls onto the user or users.

It should be noted that this phenomenon of condensation on the inner face of the wall of said article can be observed without a user in the sheltered area, simply because of the heat given off by the ground and/or the surrounding heat and/or the saturation of water in the atmosphere and thus the sheltered area.

The user or users may be disturbed by the runoff of this water.

Moreover, during the folding up and/or storage of the article, it remains damp, which can give rise to a risk of mould formation and also increase its weight. However, for the practice of certain activities, in particular hiking, lightweight articles are sought, which are easy to fold up and transport and/or to dry.

In order to overcome this problem, when the articles are tents, they comprise a double roof, the outer and inner textiles of which are spaced apart by an air gap of several centimetres. The textile of the interior chamber is not coated and thus allows the passage of water vapour. The exterior textile which is coated, protects the interior of the article, in this case the sheltered area, from the rain but blocks water vapour. The moisture in the ambient air will therefore condense on the inner face of the exterior textile. The user is protected by the textile of the interior chamber, the sheltered area of the article thus remains dry and protected from the runoff of condensation water. Since the condensation forms between the textile of the interior chamber and the exterior textile of the article, this solution does not however prevent the fact that the article remains damp. When hiking, the article is folded up in the morning and, not having time to dry, it is transported wet. The water carried by the wet article represents an additional load during hiking. In addition, the problem of potential mould formation is not resolved.

Furthermore, the additional cost engendered by the use of a double roof does not add value for the user. The production of a double roof has an impact on the environment by emitting greenhouse gases since its life-cycle requires energy (electricity, water, waste management linked to the double roof at the end of use). Ventilation devices are arranged on the articles in order to evacuate humidity, but this ventilation is sometimes insufficient or cannot be used optimally (for example when the outside temperature is very cool, or when the wind is strong, etc.).

With regard to tents, it is therefore sought to do away with the interior textile for protecting the users from condensation.

So-called single-wall articles are therefore known, in particular tents, i.e. comprising a single textile for protection of the users, without an interior chamber. These single-wall articles comprise a textile component comprising a coating with a layer that is impermeable to water and permeable to water vapour, or a membrane that is impermeable to water and permeable to water vapour.

However, condensation of water is still seen on the inner face of these single-walled articles, which water is able to run-off onto the users and/or the objects, increases the weight of the articles once folded up and risks mould formation if the articles are not properly dried before their storage.

It is also observed that the water must not stagnate, and therefore settle, on the outer face of the article, in order to allow water vapour originating from the sheltered area of the article to be evacuated through the article, in other words from its inner to its outer face.

Furthermore, on a clear night, a phenomenon of radiative cooling is observed, which amplifies the condensation on the inner face and/or on the outer face of the article. The condensation phenomenon described above for an article such as a tent or shelter can also occur in articles of clothing for the practice of sport, for example a lightweight mountain jacket or sailing dungarees.

There is therefore a need for a complex configured to limit the condensation of water on its inner face and/or outer face and configured to be able to be used in an article that is naturally exposed, by its use, to the formation of condensation, in order to limit the condensation of the latter, and which is lightweight and easy to fold.

There is also a need for an article that is configured to limit the condensation of water on its inner face and/or outer face.

### SUMMARY

The present disclosure relates, according to a first aspect, to a complex limiting the condensation of water, having an inner face and an outer face, said outer face being oriented directly facing the outside atmosphere, and said complex comprising, in particular being formed substantially of, from the inner face towards the outer face:
optionally, a protective substrate E; and
a substrate A that is impermeable to water and permeable to water vapour,
a textile substrate B; and
a metal M1, optionally in the form of an alloy, deposited directly on the textile substrate B and forming a metal layer C; and
optionally a protective layer D for the metal layer C; and
optionally a water repellent finish.

Advantageously, the metal layer C, combined with the substrates A and B, can limit the consequences of the phenomenon of radiative cooling while allowing water vapour to be evacuated from the inner face towards the outer face, and therefore through the substrates A and B, as well as the metal layer C.

Advantageously, said metal M1, and/or an alloy comprising said metal M1, forms a metal thin layer C, applied directly on the textile substrate B without the intermediary of an organic binder clogging the pores of the textile substrate and thus significantly altering its permeability to water vapour.

Advantageously, the metal layer C does not comprise a polymer binder.

In particular, in this document, polymer binder is understood to mean any polymer forming a matrix in which metal particles are dispersed.

Advantageously, the metal layer C can limit, or even prevent, the effects originating from the phenomenon of radiative cooling, by limiting heat transfer with the sky, in addition to the presence of the breathable substrate A.

Preferably, the metal layer C is chosen so that the outer face of the complex has a low emissivity. The metal layer C can reduce the external emissivity of the complex and thus reduce the heat loss from the textile substrate B. The heat exchanges with the outside are therefore reduced.

The textile substrate B therefore loses heat during the night.

Advantageously, a reduced heat loss in the interior environment, another words in the sheltered area of an article at least partially formed by said complex, but also a reduced heat loss of the textile substrate B, can reduce the risk of reaching the dew point in the sheltered area and thus prevent the appearance of condensation of water vapour on the cold inner face of the complex.

Preferably, said substrate A comprises substantially opposite inner and outer faces. The term “substrate A that is impermeable to water and permeable to water vapour” is understood to mean that water cannot pass through said substrate A from its outer face to its inner face but that water vapour can pass through from its inner face to its outer face.

Preferably, the inner face of said substrate A is oriented directly facing the outside of the complex, in particular directly towards the user to be protected from condensation and/or facing the sheltered area of the article comprising said complex.

Preferably, the textile substrate B comprises substantially opposite inner and outer faces.

Preferably, the outer face of the substrate A is arranged facing the inner face of the textile substrate B.

Preferably, the outer face of the substrate A is in direct contact with the inner face of the textile substrate B.

Preferably, the metal layer C comprises substantially opposite inner and outer faces.

Preferably, the outer face of the textile substrate B is facing the inner face of the metal layer C.

Preferably, the inner face of the metal layer C is in direct contact with the outer face of the textile substrate B.

Substrate a that is Impermeable to Water and Permeable to Water Vapour

In an embodiment, the substrate A comprises (or is) a membrane that is impermeable to water and permeable to water vapour, in particular a breathable membrane. The breathable membrane can be integral with the inner face of the textile substrate B:
by bonding (for example with an aqueous phase adhesive, for example an acrylic adhesive), and optionally heating in order to polymerise the adhesive and/or evaporate the solvent (in particular water), or
by heating the breathable membrane so as to soften it and then make it adhere under pressure to the inner face of the textile substrate B.

The breathable membrane may be a membrane that is marketed ready-to-use.

The breathable membrane A can be polyurethane-based or fluorinated polymer-based (for example PTFE) or even based on polyethylene glycol.

In another embodiment, the substrate that is impermeable to water and permeable to water vapour A comprises (or is) a polymer coating that is impermeable to water and permeable to water vapour, in particular a polymer coating of the inner face of the textile substrate B, more particularly applied by coating with a doctor blade or with blades, or by rollers or by any other equivalent means.

Polymer coating may comprise the application of one or more layer(s) of a liquid comprising one on more polymer(s) and/or one or more oligomer(s) and/or one or more monomer(s), in dispersion or in solution, for example an aqueous or solvent dispersion or solution.

The one or more polymer(s)/oligomer(s) can be chosen from: polyurethanes, polyacrylates and polyesters.

The breathable coating or the breathable membrane can be microporous or nanoporous so as to mechanically block the passage of liquid water and allow water vapour to pass via the micropores or nanopores, or even be hydrophilic (in particular the water vapour is chemically evacuated through the substrate A).

A person skilled in the art knows how to produce this type of substrate that is impermeable to water and permeable to water vapour A, and how to secure it to a textile substrate B.

### Protective Substrate E (Optional)

In an embodiment, the complex comprises a protective substrate E that, in particular, is directly oriented facing the outside of the complex and/or at least partially forms the inner face of the complex.

Hence, the substrate that is impermeable to water and permeable to water vapour A is arranged between the substrate E and the textile substrate B.

Said protective substrate E can protect the breathable substrate A.

Advantageously, the substrate E is permeable to water vapour.

Advantageously, the substrate E comprises through-openings having at least one dimension greater than or equal to 0.1 mm, optionally greater than or equal to 0.5 mm or to 1 mm.

It has been observed that the arrangement of such a substrate E in the complex increases the resistance to thermal evaporation of the complex, and can therefore amplify the phenomenon of condensation. Nevertheless, this embodiment can be advantageous when it is desired to improve the protection of the substrate A that is impermeable to water and permeable to water vapour from external attacks (improving resistance to abrasion, tearing, etc.). This arrangement is therefore not preferred.

Preferably, the substrate E is/comprises a textile layer, for example a fabric, a knit (for example of the mesh type), a nonwoven or a combination thereof.

The nonwoven is preferably a melt-blown or spunbond nonwoven or a combination thereof.

The substrate E is preferably very light. The substrate E preferably has a thickness less than or equal to 3 mm, more preferably less than or equal to 2 mm, in particular less than or equal to 1 mm.

Preferably, the substrate E has a mass per unit area greater than or equal to 5 g/m² and less than or equal to 150 g/m², more preferably less than or equal to 100 g/m², optionally less than or equal to 75 g/m² or 50 g/m².

By way of example, when the substrate E is/comprises a nonwoven, the substrate E has a mass per unit area greater than or equal to 5 g/m² and less than or equal to 30 g/m², for example of order 15 g/m².

By way of example, when the substrate E is/comprises a fabric or a knit, the substrate E has a mass per unit area greater than or equal to 30 g/m² and less than or equal to 60 g/m², for example of order 45 g/m².

The substrate E is not a thermal insulation substrate.

Preferably, the substrate E comprises fibres and/or filaments, for example fibres and/or filaments made of polyamide (PA 66, PA 4-6, PA 6, etc.) and/or polyester (PET or PBT), and/or polyolefin (PP, PE).

### Textile Substrate B

The textile substrate B is preferably a flexible textile that is permeable to water vapour, in other words water vapour can circulate from the inner face to the outer face of the textile substrate B.

The textile substrate B can be/comprises a fabric, a knit, a nonwoven, or a combination thereof.

Preferably, the textile substrate B is/comprises a woven textile, in particular comprises warp yarns and weft yarns. This type of woven textile generally offers better mechanical performance (tear resistance, etc.) and stable dimensions under elongation, compared with a knit for example.

The textile substrate B preferably comprises one or more multifilament yarn(s) and/or one or more fibre yarn(s), which can be one or more yarn(s) in one or more synthetic materials (polyethylene terephthalate, polybutylene terephthalate, polyamides, etc.) and/or natural materials (cotton, etc.) and/or regenerated materials (in particular cellulose-based, for example viscose, etc.), or a mixture thereof.

The mass per unit area of the textile substrate B is preferably less than or equal to 250 g/m², more preferably less than or equal to 200 g/m², preferably less than or equal to 150 g/m² or 130 g/m², optionally less than or equal to 100 g/m² or 90 g/m².

The mass per unit area of the textile substrate B is preferably greater than or equal to 25 g/m², more preferably greater than or equal to 50 g/m², optionally greater than or equal to 75 g/m².

Advantageously, the textile substrate B comprises pores (or through-openings) having at least one dimension greater than or equal to 0.01 mm, preferably greater than or equal to 0.1 mm, optionally greater than or equal to 0.5 m or 1 mm.

Advantageously, the textile substrate B is permeable to water vapour.

Advantageously, the crossing spaces between the yarns of substrate B form spaces for circulation of water vapour between the inner and outer faces of the substrate B.

### Metal Layer C

Preferably, said metal layer C is deposited by a thin film deposition technique, in particular such as described below or with reference to the fourth aspect of the present disclosure.

Preferably, said metal layer C has a thickness less than or equal to 50 μm, preferably less than or equal to 10 μm, in particular less than or equal to 1 μm, in particular less than or equal to 200 nm or 150 nm or 100 nm.

Preferably, said metal layer C has a thickness greater than or equal to 1 nm, preferably greater than or equal to 10 nm.

Advantageously, the metal layer C is produced by a physical vapour deposition method (PVD), in particular chosen from:
a vacuum evaporation deposition method (in particular according to the first embodiment of the fourth aspect of the present disclosure), or
preferably, a sputtering deposition method (in particular according to the second embodiment of the fourth aspect of the present disclosure, optionally enhanced by a magnetic field.

The protective metal layer D can be produced:
by a physical vapour deposition (PVD) method, in particular chosen from:
a vacuum evaporation deposition method (in particular according to the first embodiment of the fourth aspect of the present disclosure), or
a sputtering deposition method (in particular according to the second embodiment of the fourth aspect of the present disclosure, optionally enhanced by a magnetic field), in particular in the same production chamber as the metal layer C,
or can even be produced by a plasma-enhanced chemical vapour deposition method (PECVD), in particular in the same production chamber as the metal layer C. Advantageously, the use of a thin film deposition technique enables the permeability to water vapour of the textile substrate B, or of the metal layer C, to not be significantly altered, while lowering the level of emissivity of the outer face of the complex, thus limiting effects linked to the phenomenon of radiative cooling.

Advantageously, the metal layer C or the, in particular metallic or non-metallic, protective layer D, is permeable to water vapour.

### Complex

Preferably, the complex according to the present disclosure is flexible, in particular it has a certain drapability and can conform to different shapes of articles.

The flexible complex can be sewn, and thus perforated by sewing needles.

Preferably, the total mass per unit area of the complex is greater than or equal to 10 g/m² or 30 g/m² or 50 g/m².

Preferably, the mass per unit area of the complex is less than or equal to 350 g/m², more preferably less than or equal to 300 g/m² or 250 g/m² or 200 g/m², optionally less than or equal to 150 g/m² or 100 g/m².

Preferably, the complex has a thickness greater than or equal to 0.01 mm or 0.05 mm. Preferably, the complex has a thickness less than or equal to 5 mm or 4 mm or 3 mm or 2 mm or 1 mm.

In the present text, “outside atmosphere” shall be understood to mean all that is disposed outside the complex according to the present disclosure; the outer face is in particular intended, during operation, to be oriented towards the outside atmosphere, in particular towards the sky.

Chemical analysis of the outer face of the complex can be carried out by energy-dispersive x-ray spectroscopy. This is a qualitative analysis. During such a measurement, the surface chemical composition of the sample is identified, in this case the presence of the metal M1 of the metal layer C, in particular aluminium, and possibly traces of silica.

In an embodiment, the textile substrate B comprises through-openings extending between the outer and inner faces of said textile substrate B which are free of said metal layer C, and optionally of the protective layer D.

Advantageously, the metal layer C and/or the protective metal layer D, or even the non-metallic protective layer D, is/are deposited on the fibres and/or the yarns of the textile substrate B, and hence do not clog the through-openings of the textile substrate B.

In particular, the through-openings of the textile substrate B extend to and open onto the inner and outer faces of the textile substrate B.

These through-openings may comprise through-openings extending between two woven or knitted yarns.

Said through-openings form areas permeable to water vapour, in particular enabling the passage of water vapour from the inner face of the textile substrate B to its outer face.

Preferably, these through-openings have an average size less than 0.01 mm². Advantageously, the through-openings on the outer face of the textile substrate B have an average size less than or equal to 0.05 mm² or 0.01 mm² or 0.0090 mm² or 0.0070 mm² or 0.0050 mm² or 0.0040 mm² or 0.003 mm².

Advantageously, the free through-openings on the outer face of the textile substrate B have an average size greater than or equal to 0.0001 mm², preferably greater than or equal to 0.001 mm².

An exemplary protocol for measuring the average size of the through-openings is as follows: samples (at least 5) are observed by scanning electron microscope at the same magnification, with the following parameters: acceleration voltage: 10-11 volts; beam aperture size: 5.5-6; pressure in the chamber: 130 pascals; magnification: ×100; detector used: ABS lens.

The image analysis is carried out using the Topomaps software. The analysis of the structure of the outer face of the complex uses the binary segmentation option of the Topomaps software. Three different areas are evaluated for each sample. The following information is recorded for each sample: magnification ×100, binary image, histogram of the surface distribution of pores, statistical average of the through-opening surface areas.

These through-openings are advantageously observed from the outer face of the complex, i.e. the face of the complex oriented towards the outside atmosphere, and thus not oriented towards the user.

For example, at least 50% or at least 60% or at least 70% or at least 80% or at least 90% in number of the through-opening(s) on the outer side of the complex are free of the metal layer C and/or free of the protective layer D.

For example, at least 50% or at least 60% or at least 70% or at least 80% or at least 90% in number of the through opening(s) on the outer face of the laminate have an average size of less than or equal to 0.05 mm² or 0.01 mm² or 0.0090 mm² or 0.0070 mm² or 0.0050 mm² or 0.0040 mm² or 0.003 mm².

For example, at least 50% or at least 60% or at least 70% or at least 80% or at least 90% by number of the through aperture(s) on the outer face of the complex have an average size greater than or equal to 0.0001 mm², preferably greater than or equal to 0.001 mm².

These percentages in number are calculated from the analysis of the images obtained with the Topomaps software, for example, and in a preferred manner, by calculating the number of free through openings or the size of the through openings in a square having dimensions determined so as to comprise at least 30 through openings, the calculation being performed at least three times.

Preferably, in the present text, a metal layer is understood to mean, in particular with respect to metal layer C or D, any layer not comprising metal dispersed as a filler in a polymer layer.

Preferably, in the present text, a metal layer is understood to mean any layer deposited by a thin-film deposition technique (e.g. PVD or PECVD), more preferably not via a coating or impregnation of an aqueous or solvent-based dispersion or solution of at least one polymeric binder, comprising at least one metal filler dispersed in said dispersion or solution.

In an embodiment, the complex further comprises a protective layer D for the metal layer C.

The protective layer D is preferably deposited by a thin film deposition technique.

The protective layer D can be deposited by a physical vapour deposition technique or by a plasma-enhanced chemical vapour deposition technique, in particular under vacuum.

Said physical vapour deposition technique can be a vacuum evaporation deposition method, or a sputtering deposition method, optionally enhanced by a magnetic field, as described above or below with reference to the fourth aspect of the present disclosure. In an embodiment, the metal layer D does not comprise a polymer binder.

The textile substrate B, coated with the metal layer C, can be subjected to one or more gas phase precursor(s), which react or decompose on the outer face of the metal layer C, in order to generate the desired deposit.

The protective layer D can thus be a metal layer or a chemical layer not comprising aluminium or silver or titanium, in particular a chemical layer not comprising metal. The chemical layer without metal can be silica-based (for example SiO₂) or based on materials from carbon chemistry or even polymers or oligomers.

Preferably, the protective layer D has a thickness less than or equal to 500 μm or 100 μm, more preferably less than or equal to 50 μm, preferably less than or equal to 10 μm, in particular less than or equal to 1 μm, in particular less than or equal to 200 nm or 150 nm or 100 nm.

The protective layer D preferably has a thickness greater than or equal to 1 nm or 10 nm.

The function of the protective layer D is to protect the metal layer C from oxidation and degradation due to bad weather (rain, ultraviolet, etc.).

In an embodiment, the protective layer D is a metal layer D and comprises at least one metal M2, optionally in the form of an alloy.

In particular, M2 is different from said at least one metal M1 of the metal layer C or in an alloy different from the alloy comprising the metal M1 (M2 can be identical to M1) Preferably, the metal layer D is deposited by a physical vapour deposition technique, in particular by sputtering (as described above) or a plasma-assisted chemical vapour deposition technique (PECVD).

Preferably, the metal layer D is deposited under vacuum.

Preferably, the metal M2 can be chromium or nickel or a chromium-nickel alloy or titanium.

In the present text, a thin film deposition technique/step is understood to be any physical vapour deposition technique/step (in particular as described in the present text), in particular under vacuum; or any plasma-assisted chemical vapour deposition technique/step, in particular under vacuum; or a combination thereof.

In one embodiment, the protective layer D is a metal layer comprising titanium dioxide, in particular the at least one metal M2 is titanium, more particularly, the protective layer D is also a water repellent layer.

In one embodiment, the protective layer D is a water-repellent layer.

The targeted water repellency value (as described hereafter in this text regarding the outer face of the complex) is preferably a rating of more than 3, preferably 4 or more, after at least one wash.

Advantageously, the protective layer D is a layer obtained by a thin-film deposition technique and has water-repellent properties.

In one embodiment, the protective layer D comprises titanium dioxide, in particular consists essentially of titanium dioxide.

In one embodiment, the protective layer D comprises at least 60 mass %, more particularly at least 70 mass % or at least 80 mass % or at least 90 mass % or at least about 95 mass %, of titanium dioxide.

It is understood in the present text that an element (e.g. a layer) consists essentially of one or more sub-elements when at least 90% or at least 95%, by mass or by volume, of said element is formed of said sub-element(s).

In an embodiment, the protective layer D is a layer comprising at least one polymer, in particular not comprising metal.

A person skilled in the art knows to select a polymer or an oligomer to be deposited by PECVD in order that the latter does not change the emissivity properties of the metal layer C and provides a protective function against oxidation and ultraviolet for the metal layer C.

In an embodiment, the textile substrate B comprises fibres and/or filaments, and said at least one metal M1, optionally in the form of an alloy, at least partially coats said fibres and/or said filaments.

The metal M1, optionally in the form of an alloy, is in direct contact with the surface of the fibres and/or filaments of the outer face of the textile substrate.

This arrangement is possible due to the selected deposition technique.

In an embodiment, said complex does not comprise a thermal insulation textile layer arranged between the metal layer D and the outside atmosphere.

In an embodiment, said complex does not comprise a thermal insulation textile layer. Preferably, the complex according to the present disclosure is not intended to be used in a thermal insulation article, and therefore does not comprise a thick layer of thermal insulation, for example a felt. Indeed, a layer of thermal insulation would unfavourably modify the resistance to water vapour of the complex. The water vapour, being blocked by this insulation layer, would condense on its surface and form drops of water.

In an embodiment, the complex has a resistance to water vapour (Ret) less than or equal to 50 m².Pa.W⁻¹, preferably less than or equal to 45 m².Pa.W⁻¹ or 40 m².Pa.W⁻¹ or 35 m².Pa.W⁻¹ or 30 m².Pa.W⁻¹ or 25 m².Pa.W⁻¹ or 20 m².Pa.W⁻¹ or 15 m².Pa.W⁻¹. The term “resistance to water vapour” is understood to mean the measurement of the energy necessary for water vapour to pass through the complex, from its inner face to its outer face in particular.

In particular, this involves the pressure difference of water vapour between the inner and outer faces of the complex according to the present disclosure, divided by the heat flow from evaporation per unit surface area in the direction of the gradient.

Hence, the lower Ret, the more breathing is the complex.

The resistance to water vapour (Ret) is preferably measured according to standard ISO 11092, in particular dating from (September) 2014, entitled “Textiles—Physiological effects—Measurement of thermal and water-vapour resistance under steady-state conditions (sweating guarded-hotplate test). In particular, for this measurement the complex has a thickness less than or equal to 5 mm, in particular less than or equal to 1 mm.

In an embodiment, the textile substrate B comprises through-openings the average size of which is less than or equal to 0.005 mm².

The average size of the through-openings can be measured on its inner face or its outer face.

The measurement protocol is as described above.

In an embodiment, the outer face of the complex is water repellent.

This provision prevents water from stagnating on the outer face of the complex and impairing its permeability to water vapour.

Preferably, the water repellence is measured according to standard NF EN ISO 4920, in particular dated January 2013, entitled “Textile fabrics—Determination of the resistance to surface wetting (spray test). This international standard specifies a spray test method for determining the resistance of a textile fabric to surface wetting by water. The water repellence is evaluated on a scoring scale from 1 to 5, with 5 being the best value and 1 the worst value of repellence measured.

The targeted value is preferably a score greater than 3, preferably 4 or more, after at least one washing.

The water repellence can be obtained by applying (for example through impregnation), on the outer face of the metal layer C or the protective layer D, a solution or aqueous dispersion of at least one, in particular non-fluorinated, water repellent agent such as a urethane comprising alkyl groups, or an acrylate, or a combination thereof.

Such water repellent agents and their methods of application are well-known to a person skilled in the art.

In one embodiment, the outer face of the complex is the outer face of the protective layer D.

Advantageously, the protective layer D comprises an inner side and an outer side, in particular substantially opposite each other, the outer side is oriented directly towards the outside of the complex, in particular oriented directly towards the outside atmosphere.

Advantageously, the protective layer D is water-repellent.

Advantageously, the protective layer D comprises an inner face directly facing the outer face of the metal layer C.

In an embodiment, the outer face of the complex has an emissivity less than or equal to 0.50 or 0.45 or 0.40 or 0.35 or 0.30.

Emissivity (E) is the property of the surface of a body to absorb and emit heat by radiation, expressed by the ratio between the energy radiated by this surface and that radiated by a black body at the same temperature. A black body is a theoretical object which absorbs all the electromagnetic radiation that it receives at all wavelengths. No electromagnetic radiation passes through it and none is reflected.

An emissivity less than or equal to 0.30 means that at least 70% of the solar radiation received by the outer face of the complex, in particular infrared radiation, is re-emitted into the outside atmosphere, while 30% or less of said solar radiation is absorbed and/or transmitted.

The emissivity thus depends on many parameters, including the temperature of the body in question, the direction of the radiation, the wavelength and above all the surface state of the inner and outer faces of the complex.

In the present text, the term “reflection” is understood to mean the phenomenon by which a wave incident on the surface separating two propagation media having different properties returns to the medium from which it comes; with regard to the complex in particular, the outer face acts as the first medium while the ambient air into which the outer face opens acts as the second medium.

In the present text, the term “transmission of radiation” is understood to mean the passage of radiation through a medium, without change of wavelength, in particular through the complex.

The solar radiation according to the present disclosure covers the solar spectrum, which comprises in particular visible, infrared and ultra violet radiation.

Preferably, the infrared radiation targeted in the present text comprises/is near infrared radiation and far infrared radiation, in particular comprises/is far infrared radiation.

Far infrared (FIR) is a part of the thermal radiation emitted by various bodies, such as the ground, the complex, a potential interior chamber, objects arranged in the sheltered area and finally, and above all, one or more users arranged in the sheltered area or wearing a garment comprising said article.

Far infrared waves penetrate the skin without damage and heat the tissues of the body of the user in a similar way to the sun but without harmful ultraviolet radiation. Preferably, far infrared radiation is understood to mean any radiation having wavelength greater than or equal to 5 μm.

In the present text, absorption of radiation is understood to mean the penetration, retention and assimilation of said radiation within the thickness of a material, in the case of the present disclosure, in the complex.

The rate of reflection, transmission, and absorption are defined as the fraction of the incident radiation, in particular solar radiation, which is respectively reflected, transmitted or absorbed.

The emissivity, reflection, transmission and absorption form the radiative properties of the complex.

Advantageously, the emissivity, in particular in the infrared, in particular in the far infrared, of the outer face of the complex can be measured according to standard NF EN 15976, in particular dated July 2011, entitled “Flexible sheets for waterproofing-Determination of emissivity”.

In an embodiment, the outer face of the complex is impermeable to water. The impermeability to water of the complex can be evaluated by the measurement method described in standard NF EN ISO 811, in particular dated May 2018, and entitled “Textiles-Determination of resistance to water penetration-Hydrostatic pressure test”.

In an embodiment, said at least one metal M1, optionally in the form of an alloy, is chosen from the list consisting of: aluminium, silver, gold, stainless steel, zinc, tin, lead, copper, titanium, chromium, nickel, and a mixture thereof, preferably aluminium. In an embodiment, said at least one metal M2, optionally in the form of an alloy, is chosen from the list consisting of: aluminium, silver, gold, stainless steel, zinc, tin, lead, copper, titanium (especially in the form of titanium dioxide), chromium, nickel, and a mixture thereof, preferably aluminium or titanium dioxide.

Preferably, said at least one metal M2 is different from said at least one metal M1, or said at least one metal M2 is identical to the metal M1 and the metal layer C comprises an alloy of the metal M1 which is different from the alloy of the metal M2 of the protective layer D.

In an embodiment, the inner face of the complex, in particular formed at least in part by the substrate A that is impermeable to water and permeable to water vapour, is oriented in operation directly facing the user or the object to be protected from condensation.

In operation, the inner face of the complex is preferably in contact with a layer of air. The present disclosure relates, according to a second aspect, to an article comprising at least one complex according to any one of the embodiments with reference to the first aspect of the present disclosure, said article is advantageously chosen from the list comprising: a device for protecting a user from rain and/or wind, comprising a sheltered area, in particular chosen from: a protective over-bag of a sleeping bag, a tent, awning, protection tarpaulin, umbrella, sunshade, curtain, blind; and a garment for protection against rain and/or wind.

In an exemplary embodiment, said article is a device for protection from rain and/or wind comprising a sheltered area, in particular chosen from a protective over-bag of a sleeping bag, a tent, awning and protection tarpaulin, more particularly a protective over-bag of a sleeping bag, a tent and an awning.

In an exemplary embodiment, said article is a garment for protection against rain and/or wind.

Said protective garment can be sailing dungarees, a hiking jacket, etc.

The article according to the present disclosure may be a tent.

The tent may comprise an interior chamber. However, preferably the tent does not comprise an interior chamber.

The device for protection from rain and/or of wind comprises a sheltered area, in other words an area in which a user can at least partially shelter, for example from rain, wind and/or the sun.

The inner face of the complex is at least partially in contact with a layer of air, for example a layer of air of minimum thickness (for example of order 5 mm or 3 cm to 15 cm or 20 cm), in particular extending between the complex and an interior chamber, or opening directly into the air volume of the sheltered area.

In an embodiment, the complex at least partially forms a single-walled roof or a single-walled screen of a device for protection from rain and/or wind, in particular of a tent, an awning or a sleeping bag over-bag.

This provision makes it possible to lighten the article when compared with articles existing in the prior art.

The present disclosure relates to, according to a third aspect, a tent comprising a roof of which at least one part is single-walled, and said tent comprises at least one complex according to any of the embodiments with reference to the first aspect of the present disclosure forming said at least one single-walled part.

In an embodiment, said tent comprises a single-wall roof and said tent comprises one or more complex(es) according to any one of the embodiments with reference to the first aspect of the present disclosure, or obtained by the manufacturing process according to any one of the embodiments with reference to the fourth aspect of the present disclosure, forming at least in part, or entirely, the single-wall roof.

In a first example, the tent comprises a complex forming at least in part or entirely the single-wall roof of the tent.

In a second example, the tent comprises several complexes assembled together, in particular sewn and/or welded and/or glued along their edges, forming at least in part or entirely the single-wall roof of the tent.

In one embodiment, the tent comprises a device for tensioning and holding the tent in a deployed state comprising one or more tensioning rods configured to be deployed at least partially outside the single-walled roof.

A single-wall roof in the present disclosure is understood to mean a wall or a plurality of walls joined together and delimiting the inner chamber of the single-walled tent from the external atmosphere.

The present disclosure relates, according to a fourth aspect, to a method for producing a complex limiting the condensation of water and having inner and outer faces, said outer face being oriented directly facing the outside atmosphere, in particular according to any one of the embodiments with reference to the first aspect of the present disclosure, comprising the steps (in particular the following successive steps):

a—a step of providing at least one textile substrate B having an inner face and an outer face;

b—a step of depositing a substrate A that is impermeable to water and permeable to water vapour on the inner face of said textile substrate B;

c—a step of depositing a thin layer of at least one metal M1, optionally in the form of an alloy, directly on the outer face of the textile substrate B in order to manufacture a metal layer C, in particular the step of depositing a thin layer is a physical vapour deposition step;

d—optionally, a step of applying, on the outer face of the metal layer C, of a protective layer D of said metal layer C, in particular said step d) is a step of physical or chemical vapour deposition step;

e—optionally, a step of applying, on the outer face of the metal layer C or on the outer face of the protective layer D, a water repellent finish.

Preferably, the metal layer C, and optionally the protective layer D, is/are deposited by a thin film deposition technique, in particular by vapour deposition, either physically acting on the layer C and/or protective layer D, or chemically acting on the protective layer D.

The physical vapour deposition may be a vacuum evaporation deposition method, or preferably by cathode sputtering, optionally enhanced by a magnetic field.

The technical features/alternatives/embodiments relating to the thin film deposition techniques described with reference to the fourth aspect of the present disclosure below, apply independently to the third aspect or to the second aspect or to the first aspect of the present disclosure.

### Vapour Deposition of a Thin Film C or D

Advantageously, thin film deposition step c) (especially for the manufacturing of the layer C) is a physical vapour deposition step, in particular:
a vacuum evaporation deposition step, or
preferably, a cathode sputtering deposition step, optionally enhanced by a magnetic field.

Advantageously, step d) is a thin film deposition step (especially for the manufacturing of the layer D), in particular:
a physical vapour deposition step (known as PVD for Physical Vapor Deposition), more particularly:
   a vacuum evaporation deposition step, in particular this step is carried out in the chamber for producing the metal layer C, or
a sputtering deposition step, optionally enhanced by a magnetic field, in particular this step is carried out in the chamber for producing the metal layer C, in particular is carried out under vacuum, or
preferably, a plasma-enhanced chemical vapour deposition (PECVD), in particular this step is carried out in the chamber for producing the metal layer C, or
the combination of a PVD step and a PECVD step, in particular these two steps take place at the same time.

In a first embodiment, the vacuum evaporation deposition step (in particular step c) or step d)) comprises a vacuum evaporation step of at least one metal M1 (or at least one metal M2), or at least one alloy of said metal M1 (or at least one alloy of said metal M2). The vaporisation step of said at least one metal M1 or M2, or an alloy of the latter, can be obtained by various techniques, such as thermal evaporation.

In particular, this vaporisation step comprises the provision of at least one metal M1 (or M2), optionally in the form of an alloy, in a crucible arranged in a vacuum chamber.

Advantageously, during this vaporisation step, the crucible is arranged facing the outer face of the textile substrate B when the metal layer C is to be deposited, or facing the outer face of the metal layer C when a metal layer D is to be deposited. Said at least one metal M1 or M2, or an alloy of the latter, is then vaporised, in particular by heating, and deposited by condensing on the outer face of the textile substrate B, or on the outer face of the metal layer C.

It is possible to repeat this operation several times depending on the desired thickness of the metal layer C or of the protective metal layer D.

Advantageously, and preferably, the crucible (in other words the receptacle comprising said at least one metal M1, or M2, or an alloy of M1 or M2, in the molten state) can be arranged in an extended manner facing the outer face of the textile substrate B, or the outer face of the metal layer C, this is referred to in particular as vacuum evaporation with an extended source. Preferably, in this case, the vaporised metal particles are substantially directed in vertical lines towards the textile substrate B or the metal layer C. In this case, preferably, the metal layer formed has a regular, i.e. substantially constant, thickness.

The crucible (in other words the receptacle comprising said at least one metal M1 or M2 in the molten state) can be arranged at a point facing the textile substrate B or the metal layer C, this is referred to as vacuum evaporation with a point source. Preferably, in this case, the vaporised particles are substantially directed along a circular arc. In this case, preferably, the metal layer formed has an irregular thickness because it is thicker at its centre than at the edges. It is possible to reduce the pressure applied in the chamber in order to reduce this effect. However, the speed of deposition is then reduced.

In a second, in particular preferred, embodiment, the sputtering deposition step (in particular step c) or step d)), in particular combined with a magnetic field, comprises a step of vaporisation of said at least one metal M1 or M2, or an alloy thereof, preferably obtained by various techniques, such as by electron bombardment.

In particular, this sputtering step comprises a chamber in which a diode (in other words a cathode and anode assembly) is arranged, and comprises the formation of a plasma.

In particular, the chamber comprises a sputtering target forming a cathode, said sputtering target comprises (or substantially consists of) said at least one metal M1 or M2, or an alloy thereof. The chamber also comprises an anode on which the textile substrate B, optionally coated with the metal layer C, is secured so that the outer face of the textile substrate B or the metal layer C is facing the cathode, in particular at several centimetres from the cathode.

Advantageously, said sputtering step comprises a step during which the vacuum is established in the chamber, then a certain quantity of gas is introduced, preferably argon or any other equivalent gas or a mixture thereof, an electrical voltage is applied between the two electrodes (cathode and anode) causing ionisation of the atmosphere of the chamber and the creation of a glow discharge plasma. Due to the negative potential of the target, positive ions present in the residual gas rush/flow towards the target and strike it at high speed. The metal particles of the target are torn off, vaporised while crossing the plasma and are captured by the anode. These metal particles from the target are then deposited on the textile substrate B or the metal layer C secured to the anode.

Preferably, the application of a voltage between the cathode and the anode is coupled with the use of a magnetic field, in particular superimposed on the target.

This provision makes it possible to further ionise gas molecules in the vicinity of the cathode and thus increases the number of collisions between the ions created and the target. The ionisation rate is therefore increased, thus enabling a higher yield of sputtering to be obtained, and ultimately of deposit. Moreover, the plasma is located towards the target due to the magnetic field, the temperature applied to the substrate is therefore lower, which is advantageous for a textile substrate B for which the temperature resistance is limited depending on the yarns/fibres used.

The sputtering deposition technique optionally enhanced by a magnetic field (referred to as magnetron sputtering) gives good results in terms of chemical and mechanical adhesion on the textile substrate B. More complex alloys can also be deposited by this technique. Finally, the deposition of metal particles takes place as close as possible to the outer face of the textile substrate B, and therefore they are deposited on the microstructures of the textile, which is favourable for preserving the permeability to water vapour.

In a third embodiment, step d) is a plasma-enhanced chemical vapour deposition step. The plasma is preferably a plasma of oxygen or a plasma of argon or a plasma of an oxygen and argon mixture and also comprises a chemical precursor, for example an organosilicon compound, for example a linear or cyclic siloxane or for example a metal M2, e.g. titanium or aluminium, preferably titanium, or preferably a compound comprising the metal M2 (e.g. titanium).

For example, the compound comprising the metal M2 may be titanium iso-propoxide (TTIP).

Advantageously, when the metal M2 is titanium, the protective layer D is a metallic layer of titanium dioxide.

In general, a person skilled in the art knows the various physical or chemical vapour deposition techniques, and knows how to apply the thin films C and D according to the target criteria.

Advantageously, the use of a thin film deposition technique enables the permeability to water vapour of the textile substrate B, or of the metal layer C, to not be significantly altered, while lowering the level of emissivity of the outer face of the complex, thus limiting effects linked to the phenomenon of radiative cooling.

In a fourth embodiment, the metal layer C, and/or the protective layer D, is/are deposited on the outer face of the textile substrate B associated with the substrate that is impermeable to water and permeable to water vapour A, in particular the substrate A is arranged on the inner face of the textile substrate B.

In a fifth embodiment, the metal layer C is deposited on the outer face of the textile substrate B, said textile substrate B not being associated with the waterproof and water vapour permeable substrate A when depositing the metal layer C.

In a sixth embodiment, optionally in combination with the fifth embodiment, the metal layer D is deposited on the outer face of the textile substrate B, said outer face of the textile substrate B being covered at least in part by the metal layer C, said textile substrate B not being associated with the waterproof and water vapour permeable substrate A when depositing the metal layer D.

In an embodiment, said steps are performed in this order:

a— a step of providing at least one textile substrate B having an inner face and an outer face, then

c— a step of depositing a thin layer of at least one metal M1, possibly in the form of an alloy, directly on the outer face of the textile substrate B to manufacture a metal layer C, in particular the step of depositing a thin layer is a physical vapour deposition step; then

d— optionally a step of depositing, on the outer face of the metal layer C, a protective layer D of said metal layer C; and

b— a step of depositing a waterproof and water vapour permeable substrate A on the inner face of said textile substrate B.

Advantageously, the layer C is deposited on the textile substrate B free of the waterproof and water vapour permeable substrate A so that only the textile substrate B is coated at least partly with the layer C.

Advantageously, the waterproof and water vapour permeable substrate A is not coated with the metal layer C and/or the metal layer D.

In addition, the thin-film deposition technique allows the C-layer and possibly the D-layer to bond only to the textile parts of the textile substrate B without clogging its pores. Thus, water vapour flows more easily through the substrate A (in particular not clogged by layer C and/or layer D) and then through the pores of the textile substrate B (in particular not clogged by layer C and/or layer D).

In an embodiment, step d) is a thin film deposition step of the protective layer D, in particular a physical vapour deposition step of at least one metal M2 (more particularly different from metal M1 or identical to metal M1 but in an alloy different from the alloy of metal M1) or a chemical vapour deposition step of at least one chemical compound not comprising metal, or a step of chemical vapour deposition of titanium dioxide, on the outer face of the metal layer C in order to form the protective layer D.

Chemical compound not comprising metal shall be understood to mean any compound comprising carbon and/or oxygen, and optionally comprising silicon atoms (Si). In one embodiment, step d) is a step of depositing a thin layer of the protective layer D, in particular a step of depositing a metallic protective layer D comprising titanium dioxide.

In an embodiment, the complex comprises from the inner face towards the outer face:
optionally a protective textile layer E;
a substrate that is impermeable to water and permeable to water vapour A, in particular comprising a membrane that is impermeable to water and permeable to water vapour or a polymer coating that is impermeable to water and permeable to water vapour;
a textile substrate B;
a metal layer C, preferably deposited by a thin film deposition technique;
optionally a protective layer D of the metal layer C, preferably deposited by a thin film deposition technique, more preferably a protective metal layer D, for example a protective layer D in titanium dioxide, or a protective polymer layer D;
optionally a water repellent finish, in particular in order to make the outer face of the complex water repellent or when the protective layer D is a titanium dioxide layer, the protective layer D is also water-repellent.

The present disclosure relates, according to a fifth aspect of the present disclosure, to the use of a complex according to any one of the embodiments according to a first aspect of the present disclosure, or which can be obtained by implementing the method according to a fourth aspect of the present disclosure, for producing an article limiting, or even preventing, the condensation of water on an interior wall, in particular for the manufacture of at least one single-walled part of a tent roof.

Advantageously, said article comprises said complex and at least one interior wall of said article comprises/(is at least partially formed by) the inner face of the complex. Advantageously, the outer face of the article oriented towards the outside atmosphere comprises/(is at least partially formed by) the outer face of the complex.

Said article is preferably a device for protecting a user from rain and/or wind, comprising a sheltered area, in particular chosen from: a protective over-bag of a sleeping bag, a tent, an awning, a protection tarpaulin, an umbrella, a sunshade, a curtain, a blind; and a garment for protection against rain and/or wind, more preferably a device for protecting a user from rain and/or wind, comprising a sheltered area, in particular chosen from a protective over-bag of a sleeping bag, a tent and an awning.

Said article may be an article as defined with reference to the second aspect of the present disclosure.

In general, the alternatives/embodiments according to a first, second, third, fourth and fifth aspect can be combined with one another, independently of one another.

### DESCRIPTION OF THE DRAWINGS

The present disclosure will be better understood upon reading the following description of embodiments of the present disclosure, given solely as non-limiting examples and with reference to the attached drawings, wherein:

FIG. 1 schematically illustrates, in cross-section, a first example of a complex according to the present disclosure;

FIG. 2 schematically illustrates, in cross-section, a second example of a complex according to the present disclosure;

FIG. 3 schematically shows a comparative example of a complex from the prior art;

FIG. 4 schematically shows a first example of an article according to the present disclosure which is a single-walled tent comprising the first or second example shown in FIGS. 1 and 2;

FIG. 5 schematically shows a photograph taken with a scanning electron microscope, of the outer face of a textile substrate B for which the inner face is free and the outer face is covered with a metal layer C, the complex therefore does not comprise a substrate that is impermeable to water and permeable to water vapour A;

FIG. 6 schematically shows a photograph taken with a scanning electron microscope, of the outer face of a textile substrate B for which the inner face is covered with a coating that is impermeable to water and permeable to water vapour forming the substrate A, and the outer face is covered with a metal layer C;

FIG. 7 schematically shows a photograph taken with a scanning electron microscope, of the outer face of a textile substrate B for which the inner face is covered with a membrane that is impermeable to water and permeable to water vapour forming the substrate A, and the outer face is covered with a metal layer C;

FIG. 8 schematically represents a second example of an article according to the present disclosure which is a single-walled tent comprising the first or second example shown in FIGS. 1 and 2.

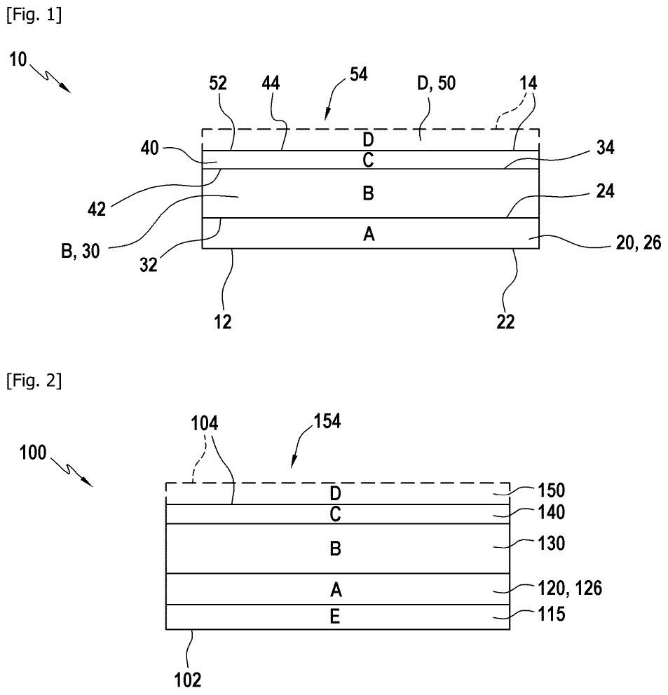

### DESCRIPTION OF THE EMBODIMENTS

The first example of a complex according to the present disclosure 10 comprises a substantially opposite inner face 12 and outer face 14. The complex 10 comprises a substrate A that is impermeable to water and permeable to water vapour 20 having substantially opposite inner 22 and outer faces 24. Advantageously, the substrate A consists of a polymer coating that is impermeable to water and to water vapour 26, for example made of polyurethane and microporous. The complex 10 comprises a textile substrate B, 30 having substantially opposite inner 32 and outer 34 faces, for which the inner face 32 is arranged facing the outer face 24 of the substrate A, 20. The complex 10 comprises a metal layer C, 40 having substantially opposite inner 42 and outer 44 faces, for which the inner face 42 is arranged facing the outer face 34 of the textile substrate B. The substrate A, 20, the textile substrate B, 30 and the metal layer C, 40 are thus substantially stacked.

Advantageously, the metal layer C, 40 is a metal layer made of a metal M1, preferably M1 is aluminium.

Optionally, the complex 10 comprises a protective layer D, 50 for the metal layer C. The protective layer D, 50 comprises substantially opposite inner 52 and outer 54 faces. The inner face 52 of the protective layer D, 50 is arranged facing the outer face 44 of the metal layer C, 40.

In this specific example, the protective layer D, 50 is a metal layer comprising a metal M2, in particular in the form of an alloy, in particular it is nickel-chromium.

Advantageously, the outer face 14 of the complex 10 is intended to be oriented directly towards the outside atmosphere, while the inner face 12 is intended to be oriented towards the user, in particular facing a sheltered area in which the user can shelter/be stationed.

The metal layer C, 40 and optionally the metal layer D, 50 is/are preferably deposited by physical vapour deposition, in particular by sputtering, in particular enhanced by a magnetic field. The metal layer C, 40 has a thickness, for example, of order 80 nm. The metal layer D, 50 has a thickness, for example, of order 80 nm.

Alternatively, the protective layer D is deposited during a chemical vapour deposition step, in particular plasma-enhanced, preferably the plasma comprises molecular nitrogen or argon, and at least one chemical predecessor, for example an organosilane. Preferably, the outer face 54 of the protective layer D is treated with a water repellent finish, in particular based on a non-fluorinated flame retardant.

In an alternative example, when the protective layer D is a thin layer of titanium dioxide, the outer face of the protective layer D does not require water-repellent treatment as it inherently provides a water-repellent function.

The second example of a complex according to the present disclosure 100 comprises, from its inner face 102 towards its outer face 104: a protective textile layer E, 115, a substrate A that is impermeable to water and permeable to water vapour 120 consisting of a polymer coating that is impermeable to water and to water vapour 126, for example polyurethane and microporous, a textile substrate B, 130, a metal layer C, 140 and optionally a protective layer D, 150.

Advantageously, the protective layer D, 150 in this specific example is a metal layer comprising a metal M2 in particular in the form of an alloy, in particular it is nickel-chromium.

Advantageously, the metal layer C, and optionally the metal layer D, is/are preferably deposited by physical vapour deposition, in particular by sputtering. The metal layer C, 140 has a thickness, for example, of order 80 nm. The metal layer D, 150 has a thickness, for example, of order 80 nm. The metal layer C, 140 comprises a metal M1, preferably aluminium.

Alternatively, the protective layer D is deposited during a chemical vapour deposition step, in particular plasma-enhanced, preferably the plasma comprises molecular nitrogen or argon, and at least one chemical predecessor, for example an organosilane. Alternatively, the substrate A is a membrane that is impermeable to water and permeable to water vapour, in particular microporous and made of polyurethane. Preferably, the outer face 154 of the protective layer D, 150 is treated by a water repellent finish, based on a flame retardant chosen from those cited above.

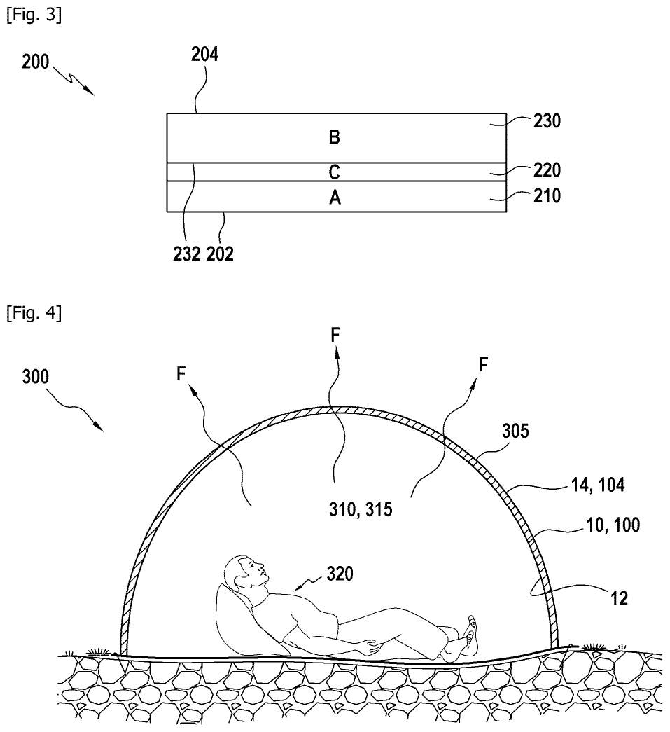

The comparative example of a complex 200 shown in FIG. 3 comprises, from its inner face 202 towards its outer face 204: a substrate A comprising a polymer coating that is impermeable to water and permeable to water vapour 210, a metal layer C, 220, and a textile substrate B, 230.

The emissivity of the outer face 204 of the complex 200 is of order 0.65 and the Ret is of order 13 m².Pa.W⁻¹. When the metal layer C, 220 is arranged on the inner face 232 of the textile substrate B, 230, the emissivity of the outer face 204 is too high, and insufficient to effectively combat radiative heating of the inner face 202 of the complex 220.

The textile substrate B described in the above examples may be a fabric comprising yarns having a fineness of 150 deniers, in particular made of polyethylene terephthalate, and having a mass per unit area of 90 g/m².

In an alternative example, the protective layer D (50 or 150) is a thin layer of titanium dioxide which also acts as a water-repellent layer. The protective layer D is then deposited in a chemical vapour deposition step, in particular assisted by plasma, preferably the plasma comprises diazote or argon, and at least one chemical precursor which is titanium or titanium dioxide to form a titanium dioxide layer. Preferably, the deposition of the thin layer D is carried out under vacuum.

In an example of a manufacturing process according to the present disclosure, the complex 10 or 100 is manufactured by first applying the metal layer C (40 or 140) to the outer side 34 of the textile substrate B (30 or 130), then applying the protective layer D (50 or 150 or a thin layer of titanium dioxide) to the outer side 44 of the metal layer C, and finally applying the waterproof-breathable substrate A to the inner side 32 of the textile substrate B. This stacking order of the laminate layers optimises the RET because the evaporation of water vapour through the substrate A is facilitated, and thus an improved anti-condensation effect is obtained.

FIG. 4 shows, in cross-section, a non-limiting example of an article 300 which is a single-walled tent 305 comprising a complex 10 or 100 according to the present disclosure.

The article comprises a sheltered area 310 in which a user 320, or an object, can shelter from the sun, wind and rain. In this specific example, the sheltered area 310 is the interior chamber 315 of the single-walled tent 305. The water vapour accumulated in the interior chamber 315 is removed according to the arrows F by passing through the complex 10 or 100 from its inner face 12 or 102 towards its outer face 14 or 104, until in the outside atmosphere. The water vapour and the accumulated heat can be removed from the interior chamber through the properties of the complex according to the present disclosure. The water vapour being removed from the sheltered area, and the temperature difference between the inner and outer faces of the complex being attenuated, the water vapour does not condense on the inner face of the complex. The complex thus remains dry on its inner face, improving user comfort. The article 300 is thus lightened, the conventional interior chamber being done away with. This provision facilitates transport of the article and reduces the number of components necessary for its production, which improves its recyclability.

FIG. 8 schematically represents a second example of an article according to the present disclosure which is a single wall tent 400 comprising a complex 10 or 100 according to the present disclosure. In particular, the single-walled tent 400 comprises a single-walled roof 410, and thus does not comprise an inner chamber covered by the single-walled roof. The single walled roof alone forms an inner chamber.

Advantageously, the single-walled roof 410 is formed of a plurality of complexes 10 or 100 joined together.

Preferably, the tent 400 also comprises a device for tensioning and holding the single-walled tent 420 in a deployed state.

The tests described below have been carried out on various constructions of complexes according to the present disclosure and comparative complexes. Comparative example 1: a comparative complex comprising a polyurethane coating that is impermeable to water vapour, a textile substrate (for example comprising PET yarns having a fineness of 75 deniers, and weighing of order 64 g/m²), a metal layer C of 80 nm, and a water repellent finish, said complex having a weight/m² of 89 g/m², a thickness of 0.15 mm, has: Ret of 222 m².Pa.W⁻¹, water repellence grade 4 and impermeability 8017 mm of water column. The Ret is very high, water vapour accumulates on the inner face of the complex, condenses and forms drops.

Comparative example 2: a comparative complex comprising a textile substrate (for example comprising PET yarns having a fineness of 75 deniers, and weighing of order 64 g/m²), a metal layer C of 80 nm, and a water repellent finish, said complex having a weight/m² of 68 g/m², a thickness of 0.10 mm, has: emissivity 0.28, Ret 3.54 m².Pa.W⁻¹, water repellence grade 4, and impermeability 97.7 mm of water column. The Ret is very low. However, the complex is permeable to water and does not therefore protect the user from rain.

Example according to the present disclosure 1: a complex according to the present disclosure comprising a polyurethane coating permeable to water vapour and impermeable to water, a textile substrate (for example comprising PET yarns having a fineness of 75 deniers, and weighing of order 75 g/m²), a metal layer C of 80 nm, and a water repellent finish, said complex having a weight/m² de 83 g/m², a thickness de 0.15 mm, has: emissivity 0.30, Ret 11.4 m².Pa.W⁻¹, water repellence grade 3, and impermeability 6396 mm of water column. In use (for example forming the single-walled roof of a tent), no condensation forms on the inner face of the complex, which remains dry even after a night of sleeping.

Example according to the present disclosure 2: a complex according to the present disclosure comprising a membrane permeable to water vapour and impermeable to water, a textile substrate (for example comprising PET yarns having fineness 75 deniers, and weighing of order 64 g/m²), a metal layer C of 80 nm, and a water repellent finish, said complex having a weight/m² of 92 g/m², a thickness of 0.15 mm, has: emissivity 0.26, Ret 13 m². Pa.W-1, water repellence grade 4.5, and impermeability 5998 mm of water column. In use (for example forming the single-walled roof of a tent), no condensation forms on the inner face of the complex, which remains dry even after a night of sleeping.

Example according to the present disclosure 3: a complex according to the present disclosure comprising a protective layer E in a mesh textile (made of PET of 50 g/m²), a membrane permeable to water vapour and impermeable to water, a textile substrate (for example comprising PET yarns having a fineness 75 deniers, and weighing of order 64 g/m²), a metal layer C of 80 nm, and a water repellent finish, said complex having a weight/m² de 150 g/m², a thickness 0.33 mm, has: emissivity 0.26, Ret 32.1 m².Pa.W⁻¹, water repellence grade 4.5, and impermeability 22531 mm of water column. In use (for example forming the single-walled roof of a tent), no condensation forms on the inner face of the complex, which remains dry even after a night of sleeping. This type of complex can be interesting if seeking to improve the protection of the substrate A against abrasion. However, in practice, it has been observed that examples 1 and 2 provide very good performance with regard to the non-formation of condensation on the inner face of the complex and this without protective layer E.

The deposition of a protective thin film D in examples 1 to 3 according to the present disclosure on the metal layer C, and the water repellent finish being applied on the protective layer D, does not change the measured Ret and emissivities. The protective layer D can prevent oxidation of the metal layer C and prolong its lifespan.

In the examples above, the metal layer C is deposited by magnetron sputtering (i.e enhanced by a magnetic field).

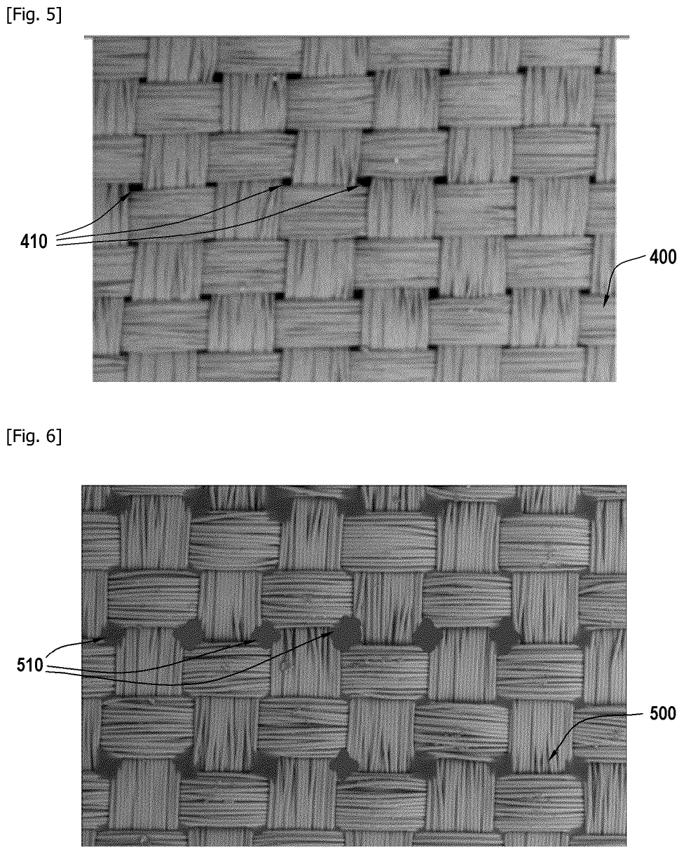

Other equivalent techniques for physical thin film deposition could be used if they provide the same performance in terms of adhesion on the textile substrate B, emissivity and Ret. A person skilled in the art knows these physical or chemical vapour deposition techniques, and knows which parameters to retain in order to achieve, in particular, the emissivity and Ret values determined in the present disclosure. FIGS. 5 to 6 show photographs of the through-openings of a textile substrate B (400, 500, 600) measured according to the measurement protocol described above (in particular with scanning electron microscope and the Topomaps software).

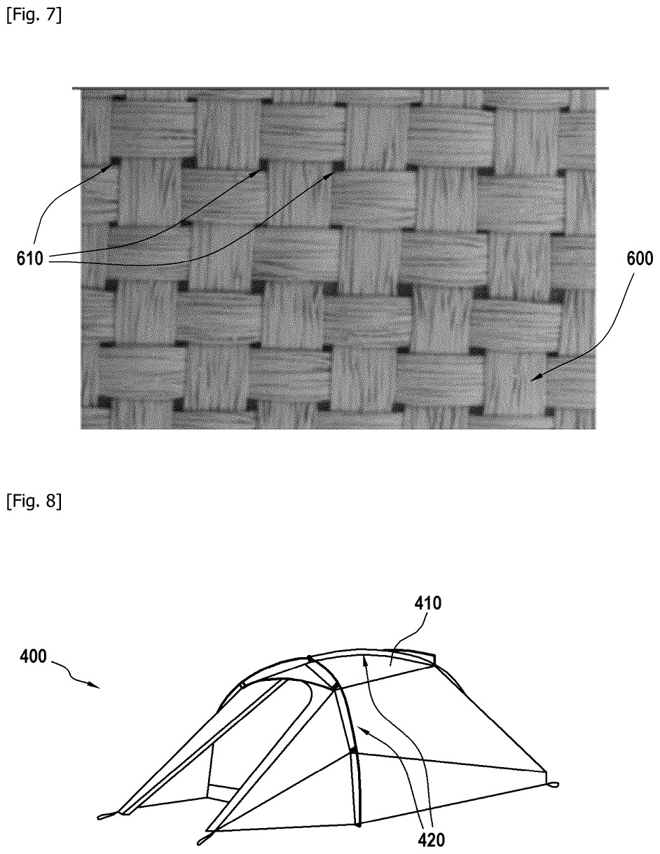

Through-openings 410 can be seen in FIG. 5, 510 in FIG. 6 or again 610 in FIG. 7. These through-openings (410, 510, 610) extend and open out on the inner and outer faces of the textile substrate B (400, 500, 600). The textile substrate B (400, 500, 600) is, in particular, a warp and weft fabric of 64 g/m² comprising PET yarns having a finesse of 75 deniers).

The metal layer C is preferably an 80 nm aluminium layer deposited by magnetron sputtering.

The through-openings are advantageously formed at the intersection of the yarns with one another as can be seen in FIGS. 5 to 7.

It is observed in FIG. 5 that the metal layer C does not clog the through-openings 410 of the textile substrate B, 400 but that said at least one metal M1, in this case aluminium, is deposited on the yarns.

In FIG. 6, the through-openings 510 are clogged from the inner face of the textile substrate B by the coating that is impermeable to water and permeable to water vapour forming the substrate A. However, this substrate A being permeable to water vapour, the water vapour passes through the substrate A then escapes via said through-openings 510 through the textile substrate B, and the metal layer C, and optionally the protective layer D (which also adheres to the yarns/fibres and does not clog the openings 510).

In FIG. 7, the substrate A is a membrane that is impermeable to water and permeable to water vapour, laminated on the inner face of the textile substrate B. The membrane therefore does not clog the through-openings 610 of the textile substrate B, and is therefore not visible from its outer face.

In general, the substrate A comprises micropores enabling the evacuation of water vapour but do not allow liquid water to pass through. These through-openings 410, 510 or 610 preferably have an average size less than or equal to 0.01 mm², more preferably less than or equal to 0.003 mm² and greater than or equal to 0.0001 mm², for example of order 0.001 to 0.01 mm².

1. A complex reducing the condensation of water, having an inner face and an outer face, said outer face being oriented directly facing the outside atmosphere, and said complex comprising:
from said inner face towards said outer face:
a substrate A that is impermeable to water and permeable to water vapour; and
a textile substrate; and
at least one metal M1, optionally in the form of an alloy, deposited directly on the textile substrate and forming a metal layer C.

2. The complex according to claim 1, wherein the textile substrate comprises through-openings extending between its outer and inner faces, which are free from said metal layer C.

3. The complex according to claim 1, wherein said complex further comprises a protective layer D for the metal layer C.

4. The complex according to claim 3, wherein—the protective layer D is a metal layer and comprises at least one metal M2, optionally in the form of an alloy.

5. The complex according to claim 3, wherein—the protective layer D is a metal layer comprising titanium dioxide. particularly and the protective layer D is also a water repellent layer.

6. The complex according to claim 3, wherein the protective layer D is a layer comprising at least one polymer.

7. The complex according to claim 1 6, wherein the textile substrate B comprises fibres and/or filaments, and wherein at least one metal M1, optionally in the form of an alloy, at least partially coats said fibres and/or said filaments.

8. The complex according to claim 1, wherein said complex has a total thickness less than or equal to 5 mm.

9. The complex according to claim 1, wherein said complex does not comprise a thermal insulation textile layer.

10. The complex according to claim 1, wherein the complex has a resistance to water vapour (Ret) less than or equal to 50 m².Pa.W⁻¹.

11. The complex according to claim 1, wherein the outer face of the complex is water repellent.

12. The complex according to claim 1, wherein the outer face of the complex has an emissivity less than or equal to 0.50.

13. The complex according to claim 1 wherein said at least one metal M1 is chosen from the list consisting of: aluminium, silver, gold, stainless steel, zinc, tin, lead, copper, titanium, nickel, chromium, and a mixture thereof.

14. The complex according to claim 1, wherein the inner face of the complex is oriented in operation directly facing the user or the object to be protected from condensation.

15. An article comprising at least one complex according to claim 1, wherein said article is chosen from the list comprising: a device for protection from rain and/or wind, comprising a sheltered area and a blind; and a garment for protection against rain and/or wind.

16. The article according to claim 15, wherein the complex at least partially forms a single-walled roof or a single-walled screen of said device for protection from rain and/or wind.

17. A tent wherein said tent comprises a roof at least a portion of which is single-walled, and wherein said tent comprises at least one complex according to claim 1 forming said at least one single-walled portion.

18. A manufacturing method of a complex limiting the condensation of water, having inner and outer faces, said outer face being oriented directly facing the outside atmosphere, wherein said method comprises:
a—a step of providing at least one textile substrate B having an inner face and an outer face,
b—a step of depositing a substrate A that is impermeable to water and permeable to water vapour on the inner face of said textile substrate B,
c—a step of depositing a thin layer of at least one metal M1, optionally in the form of an alloy, directly on the outer face of the textile substrate B in order to manufacture a metal layer C,
d—optionally a step of depositing, on the outer face of the metal layer C, a protective layer D of said metal layer C.

19. The manufacturing method according to claim 18, wherein said steps are performed in this order:
a—a step of providing at least one textile substrate B having an inner face and an outer face, then
c—a step of depositing a thin layer of at least one metal M1, optionally in the form of an alloy, directly on the outer face of the textile substrate B to manufacture a metal layer C, then
d—optionally a step of depositing, on the outer face of the metal layer C, a protective layer D of said metal layer C; and
b—a step of depositing a waterproof and water vapour permeable substrate A, on the inner face of said textile substrate B.

20. The method according to claim 18, wherein said method comprised a step d) depositing, on the outer face of the metal layer C, a metallic protective thin layer D of said metal layer C.

21. A method for manufacturing at least a single-walled portion of an article limiting, or even preventing, the condensation of water on an interior of said single-wall portion, said article being chosen among: a tent roof, a protective over-bag of a sleeping bag, an awning, a protection tarpaulin, an umbrella, a sunshade, a curtain, a blind, and a garment for protection against rain and/or wind, wherein said method comprises a step of implementing a complex according to claim 1.

22. The manufacturing method according to claim 18, wherein said method comprises a step d) of depositing, on the outer face of the metal layer C, a protective layer D of said metal layer C, and wherein step c) and d) are each a step of depositing a thin metallic layer, said step of depositing a thin metallic layer comprising a physical vapour deposition step.

23. The article according to claim 15, wherein said device for protection from rain and/or wind, comprising a sheltered area, is chosen from: a protective over-bag of a sleeping bag, a tent, an awning, a protection tarpaulin, an umbrella, a sunshade, a curtain, and a blind.
